(19) United States
(12) Patent Application Publication
(10) Pub. No.: US 2004/0023466 A1
(43) Pub. Date: Feb. 5, 2004

(54) Stacked wafer aligment method

(76) Inventor: Akira Yamauchi, Shiga (JP)

Correspondence Address: SMITH PATENT OFFICE, 1901 PENNSYLVANIA AVENUE N W, SUITE 200, WASHINGTON, DC, 20006

(21) Appl. No.: 10/381,740

(22) PCT Filed: Oct. 5, 2001
(86) PCT No.: PCT/JP01/08799

(30) Foreign Application Priority Data
Oct. 10, 2000 (JP) 2000-309670

(51) Int. Cl. H01L 21/66; H01L 21/76

(52) U.S. Cl. 438/401; 438/16; 414/936

(57) ABSTRACT

A stacked wafer alignment method with ease and with high precision in which a recognition mark for alignment is provided on each wafer, three or more wafers are stacked while adjacent two wafers are aligned with each other and the positions of the recognition marks of the wafers are shifted in the circumferential direction from one another in order.

### Technical Field of the Invention The present invention relates to an alignment method for positioning adjacent wafers when three or more wafers are stacked.

Background Art of the Invention

For example, in a mounting device for bonding wafers, an aligner for aligning a wafer at a predetermined position in order to process the wafer or to mount a chip or other parts on the wafer, or an exposure device for providing a predetermined exposure to a wafer, it may be required to stack a plurality of wafers, particularly, three or more wafers, in order, and to form a compact stacked body of the plurality of wafers.

To satisfy such a requirement, a wafer to be stacked must be aligned at a high accuracy relative to a lower wafer. In the conventional technology, for example, when two wafers are aligned with each other, a recognition mark for alignment has been provided on each wafer and a desired-accuracy alignment is carried out by aligning the positions of the recognition marks of both wafers.

However, if such a method is applied to stacking of three or more wafers as it is, because, after the recognition marks of adjacent wafers are aligned with each other, a recognition mark of a wafer to be stacked successively further positions at the aligned recognition mark, the respective recognition marks overlap. In such a condition, it is difficult to precisely read the recognition mark to be read, and a high-accuracy alignment becomes difficult. Therefore, in practice, a multi-layer wafer stacking by such a method has not been carried out.

### DISCLOSURE OF THE INVENTION

Accordingly, an object of the present invention is to provide a stacked wafer alignment method which enables a multi-layer wafer stacking and in which the multi-layer wafer stacking can be easily carried out at a high alignment accuracy.

To accomplish the above object, a stacked wafer alignment method according to the present invention is characterized in that a recognition mark for alignment is provided on each wafer, three or more wafers are stacked while adjacent two wafers are aligned with each other and the positions of the recognition marks of the wafers are shifted in the circumferential direction from one another in order.

In this stacked wafer alignment method, for example, a first recognition mark for alignment relative to a lower-layer wafer and a second recognition mark for alignment relative to an upper-layer wafer, the position of which is shifted relative to the first recognition mark in the circumferential direction of a wafer, are provided on each wafer of at least wafers from the second-layer wafer to a wafer immediately before the last-layer wafer. Namely, one recognition mark among the recognition marks provided at positions shifted in the circumferential direction is used for alignment with a lower-layer wafer, and the other recognition mark is used for alignment with an upper-layer wafer. Although the positions to be provided with these recognition marks are not particularly limited, if they are provided on the edges of the respective wafers, the area for recognition marks may be minimized.

As recognition marks provided on each wafer, it is preferred that recognition marks are provided on each wafer at positions in the circumferential direction which substantially face each other. Namely, by aligning a wafer relative to a lower wafer or an upper wafer using at least two recognition marks provided in the circumferential direction at positions substantially facing each other, it becomes possible to carry out alignment in angle in the rotational direction at the same time, and a more accurate alignment becomes possible.

Although means for reading recognition marks is not particularly restricted, in a case using thin wafers, it is possible that a measurement wave transmits a wafer stacked body. If a recognition mark is read by a measurement wave transmitting a wafer, it may become possible to read all recognition marks necessary for alignment from one direction of from upper side or from lower side, and efficient stacking operation and reading operation may be achieved by avoiding interference between the stacking operation and the reading operation.

In the above-described stacked wafer alignment method according to the present invention, since the positions of recognition marks are shifted in the circumferential direction for each wafer to be stacked in order, it is avoided that the recognition marks used for alignment of adjacent wafers overlap at a multiple condition, and a recognition mark to be read can be read precisely, accurately and easily, for each stacking operation. As a result, a plurality of wafers can be aligned at a high accuracy, and they can be stacked in a desired form easily at a high accuracy.

Further, a recognition mark for alignment relative to a lower-layer wafer and a recognition mark for alignment relative to an upper-layer wafer are provided on each wafer of at least wafers from the second-layer wafer to a wafer immediately before the last-layer wafer, and because these recognition marks may be provided at positions which are shifted by a merely appropriate predetermined amount in the circumferential direction of a wafer, an operation substantially does not increase as compared with a usual operation for providing recognition marks. Moreover, if these recognition marks are provided so as to be shifted in the circumferential direction at the edge portion of a wafer, without giving any influence to a functional region of each wafer, the area for the recognition marks may be minimized.

### BRIEF EXPLANATION OF THE DRAWINGS

FIG. 1 is a schematic view of a mounting device for carrying out an alignment method according to an embodiment of the present invention.

FIG. 2 is a perspective view of a plurality of wafers, showing an example of the alignment method in the device depicted in FIG. 1.

FIG. 3 is a plan view of the respective wafers, showing a more concrete method for alignment shown in FIG. 2.

FIGS. 4A-4C are plan views of recognition marks showing examples of their shapes.

### THE BEST MODE FOR CARRYING OUT THE INVENTION

Hereinafter, desirable embodiments of the present invention will be explained referring to figures.

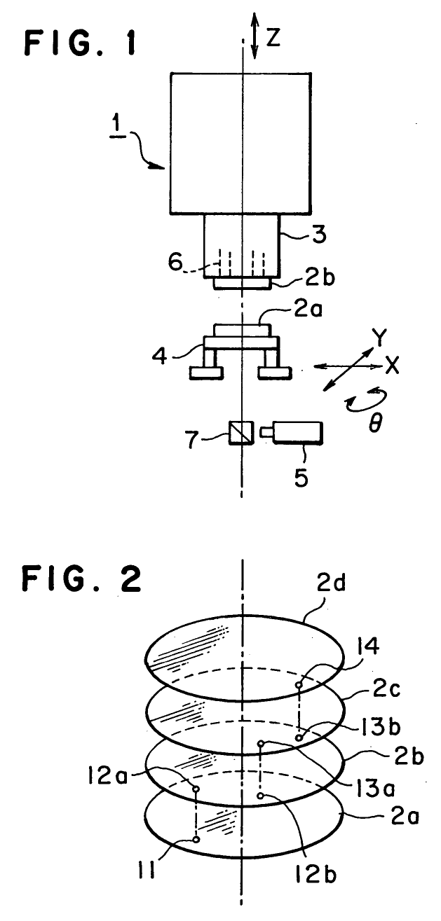

FIG. 1 shows a schematic structure of a mounting device bonding wafers for carrying out a stacked wafer alignment method according to an embodiment of the present invention. FIG. 2 shows a state for stacking wafers in order.

In FIG. 1, label 1 shows the whole of a mounting device, and labels 2a and 2b show wafers to be stacked and bonded. Although only two wafers 2a and 2b are shown in FIG. 1, in practice, as shown in FIG. 2, three or more wafers 2a, 2b, 2c, . . . are stacked in order.

In this embodiment, an upper-side wafer 2b to be stacked, shown in FIG. 1, is held on a head 3 by, for example, an electrostatic chuck and the like, and the head 3 can be moved in Z direction (vertical direction). A lower-side wafer 2a is held on a stage 4 by an electrostatic chuck and the like. In this embodiment, this stage 4 can be adjusted in position in X and Y directions (horizontal direction) and θ direction (rotational direction), and by the adjustment upper-side wafer 2b and lower-side wafer 2a can be aligned with each other. Although the positioning in X, Y and θ directions is carried out on the lower stage 4 side in this embodiment when wafers are stacked in order, the positioning may be carried out on the upper head 3 side or on both sides similarly.

The alignment is carried out by reading a recognition mark provided on each wafer by a recognition means, and aligning the positions of the recognition marks of adjacent wafers. In this embodiment, an infrared-ray camera 5 is provided as the recognition means at a position below stage 4 composed of a transparent material, and the recognition means reads a measurement wave sent from light guides 6 via a prism device 7. In a case where wafers are relatively thin and they can transmit the measurement wave, all recognition marks necessary for alignment can be read thus from one direction (from the lower direction). However, it is also possible that another recognition means, for example, a visual-ray camera (for example, a two-sight camera), is provided between the upper and lower wafers so as to be proceeded and retreated, and the upper and lower recognition marks are read by the recognition means.

Further, as an application of the above-described embodiment, except an infrared-ray camera, for example, any means for recognizing the recognition marks of wafers via a measurement wave transmitting the wafers such as an X ray, an electromagnetic wave or a sonic wave, can be employed.

In the above-described mounting device 1, the alignment according to the present invention is basically carried out as shown in FIG. 2. FIG. 2 shows an example of a case where four wafers 2a, 2b, 2c and 2d are stacked. When the respective wafers 2a, 2b, 2c and 2d are stacked in order, while a recognition mark 11 (a recognition mark of the first-layer wafer 2a), recognition marks 12a and 12b (recognition marks of the second-layer wafer 2b), recognition marks 13a and 13b (recognition marks of a wafer 2c immediately before the last-layer wafer) and a recognition mark 14 (a recognition mark of the last-layer wafer 2d), which are provided on the respective wafers 2a-2d, are shifted in the circumferential direction of the wafers in order, the positions of the recognition marks of adjacent wafers are aligned. These respective recognition marks are provided on the edge portions (radially outer portions) of the respective wafers in this embodiment.

More concretely, when wafer 2b is stacked on wafer 2a while being aligned with wafer 2a, recognition mark 11 of wafer 2a and recognition mark 12a of wafer 2b are aligned with each other. When wafer 2c is further stacked on wafer 2b, recognition mark 12b of wafer 2b and recognition mark 13a of wafer 2c are aligned with each other. When wafer 2d is further stacked on wafer 2c, recognition mark 13b of wafer 2c and recognition mark 14 of wafer 2d are aligned with each other.

Thus, in this embodiment, recognition marks 12a and 13a for alignment with lower-layer wafers 2a and 2b and recognition marks 12b and 13b for alignment with upper-layer wafers 2c and 2d are provided on wafers 2b and 2c at conditions shifted in the circumferential direction, respectively, and as mentioned above, the recognition marks of adjacent wafers to be stacked are aligned at the respective positions shifted in the circumferential direction. Therefore, the positions of the recognition marks for alignment do not overlap with each other, and for each stacking, a recognition mark to be read can be read precisely, and a high-accuracy alignment becomes possible. Consequently, a multi-layer wafer stacking, which has been difficult to be carried out at a high accuracy, can be carried out at a high-accuracy alignment condition.

In the above-described stacked wafer alignment, for example, as shown in FIG. 3, it is preferred that the recognition marks of each wafer are provided at positions which face each other in the circumferential direction of the wafer. In such a condition, because an angle in the rotational direction of a wafer can be aligned at the same time, a more accurate alignment becomes possible.

Further, as shown in FIGS. 2 and 3, if the recognition marks are provided on the edge portions of the respective wafers, without providing a particular region on each wafer, the recognition marks can be provided on a region except a predetermined functional region at a condition of a minimum area necessary for alignment.

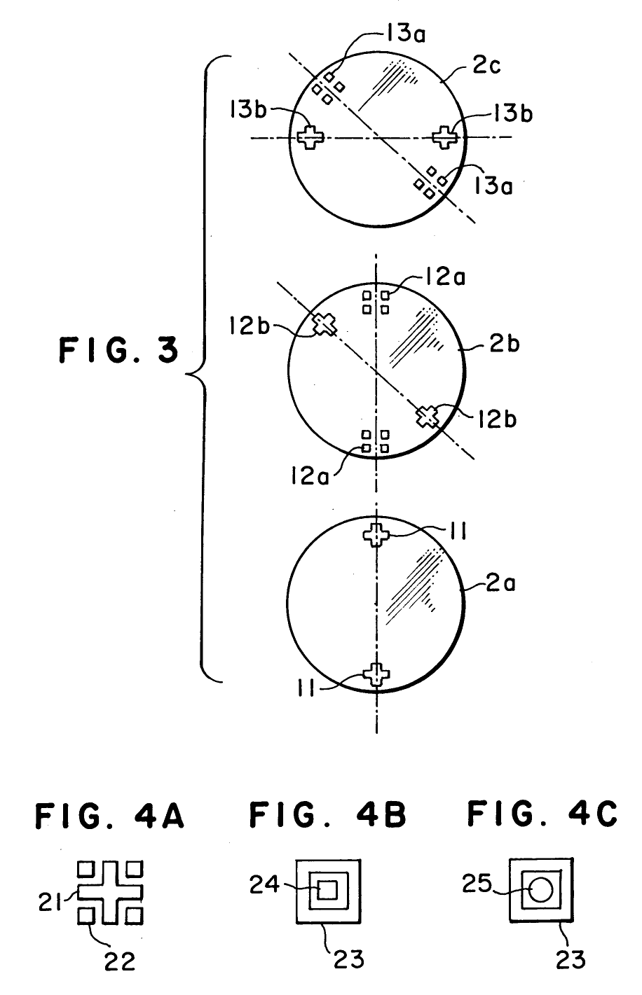

Furthermore, in the example shown in FIG. 3, the recognition mark is formed, as shown in FIG. 4A, from a cross-shaped recognition mark 21 and four small-block recognition marks 22 capable of surrounding the cross-shaped recognition mark 21 from four corners, and the condition, where both recognition marks 21 and 22 are aligned as shown in FIG. 4A, is read by a recognition means, thereby ensuring an accuracy for alignment.

The shape of a recognition mark can be set substantially arbitrarily. For example, as shown in FIG. 4B, one recognition mark 23 is formed as an inside-empty large square mark, and the other recognition mark 24 is formed as a small square mark which can enter into the recognition mark 23. Alternatively, as shown in FIG. 4C, the recognition mark, which enters into the inside-empty large square mark 23, can be formed as a circular recognition mark 25. Of course, marks with other shapes except the shapes shown in FIGS. 4A-4C may be employed.

The stacked wafer alignment method according to the present invention can be applied to an aligner in which respective wafers are merely stacked at an aligned condition, or an exposure device in which, after a wafer is exposed at a predetermined condition, thereon next wafers are stacked in order, and the same or a different exposure is carried out for the following each wafer, except the above-described mounting device for bonding wafers to each other.

### INDUSTRIAL APPLICATIONS OF THE INVENTION

The stacked wafer alignment method according to the present invention can be applied to any alignment for stacking three or more wafers in order, and it is particularly suitable for alignment of wafers with each other in a mounting device for bonding wafers to each other, an aligner for stacking wafers in order, and an exposure device for stacking wafers in order and exposing the wafers in order.

1. A stacked wafer alignment method characterized in that a recognition mark for alignment is provided on each wafer, three or more wafers are stacked while adjacent two wafers are aligned with each other and the positions of the recognition marks of the wafers are shifted in the circumferential direction from one another in order.

2. The stacked wafer alignment method according to claim 1, wherein a first recognition mark for alignment relative to a lower-layer wafer and a second recognition mark for alignment relative to an upper-layer wafer, the position of which is shifted relative to the first recognition mark in the circumferential direction of a wafer, are provided on each wafer of at least wafers from the second-layer wafer to a wafer immediately before the last-layer wafer.

3. The stacked wafer alignment method according to claim 1, wherein recognition marks are provided on each wafer at positions in the circumferential direction which substantially face each other.

4. The stacked wafer alignment method according to claim 1, wherein a recognition mark is read by a measurement wave transmitting a wafer.
